(19) United States
(12) Patent Application Publication
(10) Pub. No.: US 2015/0036828 A1
(43) Pub. Date: Feb. 5, 2015

(54) INTERNET AUDIO SOFTWARE METHOD

(71) Applicant: Lloyd Trammell, Thousand Oaks, CA (US)

(72) Inventor: Lloyd Trammell, Thousand Oaks, CA (US)

(73) Assignee: Max Sound Corporation, La Jolla, CA (US)

(21) Appl. No.: 14/273,475

(22) Filed: May 8, 2014

Related U.S. Application Data
(60) Provisional application No. 61/821,057, filed on May 8, 2013.

(51) Int. Cl. H04S 7/00; H03G 5/16; H04S 5/00

(52) U.S. Cl. CPC H04S 7/307; H04S 5/00; H03G 5/16
USPC 381/17; 381/101

(57) ABSTRACT

An audio enhancement technique comprises an audio source. Presets for the input audio sound are provided. The presetted ausio sound is tone adjusted to create a tone adjusted presetted audio. The tone adjusted presetted audio is expanded to create an expanded audio and the expanded audio is outputted for use by user. The presetted audio is subjected to a treatment by one or more modules to improve sound quality. The treatment comprises processing the audio source by the following modules: a low pass filter with dynamic offset; an envelope controlled bandpass filter; a high pass filter; and adding an amount of dynamic synthesized sub bass to the audio. The processed audio signals are combined in a summing mixer with the audio source to create an audio out signal. In one embodiment, the expanding comprises sending audio out to a block that splits, processes and combines the stereo stream into several different versions that are fed into the Stereo Bus A; feeding Stereo Bus A output to a Compare Block that adjusts the amplitude of the original and processed audio by averaging; and feeding the output from the compare block as an stereo output. In one embodiment, the tone adjustment comprises: a first section for adjusting a low frequency tone; a second section for adjusting a mid frequency tone; a third section for adjusting a high frequency tone and mixing the audio outputs processed by the first, second and third sections to produce an output audio sound.

### CROSS-REFERENCE TO RELATED PATENT APPLICATIONS

Embodiments of the present invention relate to U.S. Provisional Application Ser. No. 61/821,057, filed May 8, 2013, entitled “INTERNET AUDIO TRANSMISSION SOFTWARE”, the contents of which are incorporated by reference herein and which is a basis for a claim of priority.

### BACKGROUND OF THE INVENTION

In the internet broadcast world today there is a significant limitation on bandwidth. A recent regulation provides that providers could pay extra for faster speeds, using more of the already limited available bandwidth¹. Under these circumstances, there are two plausible solutions for providers and users. Either compress the content and accept below par quality or pay for the extra speed and bandwidth. Even if users opt to pay for the extra, by the time the content is received by user it may be compressed several times to accommodate the limitations of the corresponding internet pathway. Accordingly, there is likely to be some degradation by the time the content reaches the user. ¹ http://online.wsj.com/news/articles/SB10001424052702304049704579320500441593462; http://www.netcompetition.org/congress/the-multi-speed-internet-is-getting-more-faster-speeds

As the data begins its path, it goes through routing switches that each have limitations and these limitations are imposed upon content. Using the MAXD Internet Audio System, it is possible to use lower bitrate, compressed audio formats such as mp3 and aac to send the audio portion of the programming. This can represent a savings of up to 16.35 MB per minute. (48/24@17.28 MB vs 0.9375 128 MP3)². This also represents a fairly large amount of money when considering the amount of data transmitted by someone like Netflix. ² http://www.audiomountain.com/tech/audio-file-size.html

The inventive MAXD Internet Audio System can make the 128 mp3 sound as good or better than CD quality for the user. This system can be used with either live as a webcast or on pre-recorded material to deliver the best quality audio experience available. The software can be installed in stand alone computers or large servers as needed. There is a growing majority of content consumers switching to internet, as well as providers like Comcast and Netflix. This will tax the internet even more as this trend grows³. ³ http://compnetworking.about.com/b/2013/04/18/what-happens-when-we-run-out-of-bandwidth.htm

As users are well aware, use of a wireless computer network when it is flooded with data traffic is a chore as web pages take minutes to load (and some of the content is often missing), apps pop up error messages, and user's computer might even freeze. Wireless network bandwidth is a finite resource users often take for granted because new cell towers have sprung up in many parts of the world. But as people keep buying more computers and mobile devices and using them heavily, eventually this bandwidth will run out. At some point this may lead to regulated or voluntary cut back on usage, and also expect pay higher prices for wireless Internet. Wireless bandwidth is rapidly reaching critical levels as well⁴. Clearly, the mobile phone industry is running out of the airwaves necessary to provide voice, text and Internet services to its customers. ⁴ http://money.cnn.com/2012/02/21/technology/spectrum crunch/NEW YORK

Webcast—Internet Streamimg⁵ is a media presentation distributed over the Internet using streaming media technology to distribute a single content source to many simultaneous listeners/viewers. A webcast may either be distributed live or on demand. Essentially, webcasting is “broadcasting” over the Internet. The largest “webcasters” include existing radio and TV stations, who “simulcast” their output through online TV or online radio streaming, as well as a multitude of Internet only “stations”. The term webcasting usually refers to non-interactive linear streams or events. Rights and licensing bodies offer specific “webcasting licenses” to those wishing to carry out Internet broadcasting using copyrighted material. Webcasting is also used extensively in the commercial sector for investor relations presentations (such as annual general meetings), in e-learning (to transmit seminars), and for related communications activities. However, webcasting does not bear much, if any, relationship to web conferencing, which is designed for many-to-many interaction. The ability to webcast using cheap/accessible technology has allowed independent media to flourish. There are many notable independent shows that broadcast regularly online. Often produced by average citizens in their homes they cover many interests and topics. Webcasts relating to computers, technology, and news are particularly popular and many new shows are added regularly. Webcasting differs from podcasting in that webcasting refers to live streaming while podcasting simply refers to media files placed on the Internet. ⁵ http://webcastinc.com/what-is-webcasting/live-webcast-how-to-stream; http://prometheusradio.org/internet streaming; http://en.wikipedia.org/wiki/Streaming media

The inventive software allows an internet audio broadcast to not only de-compress a file with heavy audio compression (Volume Wars), but allows for the reconstruction of both dynamic and harmonic content. This is a combination of the MAXD APP, De-Compress, and the MS Expander software modules. The end result will be a file with much greater dynamic and harmonic content, but still in the same format as started, if desired. Any encode/decode format, MP3, AAC, etc. will happen before and after this software process. The software will internally process PCM digital audio data.

An enhanced Internet audio software system is required that addresses the above noted deficiencies of the conventional systems.

### SUMMARY OF THE INVENTION

The inventive MAXD Internet audio software technique comprises an audio source. Presets for the input audio sound are provided. The presetted audio sound is tone adjusted to create a tone adjusted presetted audio. The tone adjusted presetted audio is expanded to create an expanded audio and the expanded audio is outputted for use by user. The presetted audio is subjected to a treatment by one or more modules to improve sound quality. The treatment comprises processing the audio source by the following modules: a low pass filter with dynamic offset; an envelope controlled bandpass filter; a high pass filter; and adding an amount of dynamic synthesized sub bass to the audio. The processed audio signals are combined in a summing mixer with the audio source to create an audio out signal. In one embodiment, the expanding comprises sending audio out to a block that splits, processes and combines the stereo stream into several different versions that are fed into the Stereo Bus A; feeding Stereo Bus A output to a Compare Block that adjusts the amplitude of the original and processed audio by averaging; and feeding the output from the compare block as an stereo output. In one embodiment, the tone adjustment comprises: a first section for adjusting a low frequency tone; a second section for adjusting a mid frequency tone; a third section for adjusting a high frequency tone and mixing the audio outputs processed by the first, second and third sections to produce an output audio sound.

The inventive MAXD Internet Audio System comprises a computer with A/V inputs and an internet connection. The source can be live or existing content and this is processed before being passed on to the computers internet streaming software.

### BRIEF DESCRIPTION OF THE DRAWINGS

FIG. 1 is a block diagram showing the inventive MAXD Internet Audio Software System according to an exemplary embodiment of the present invention.

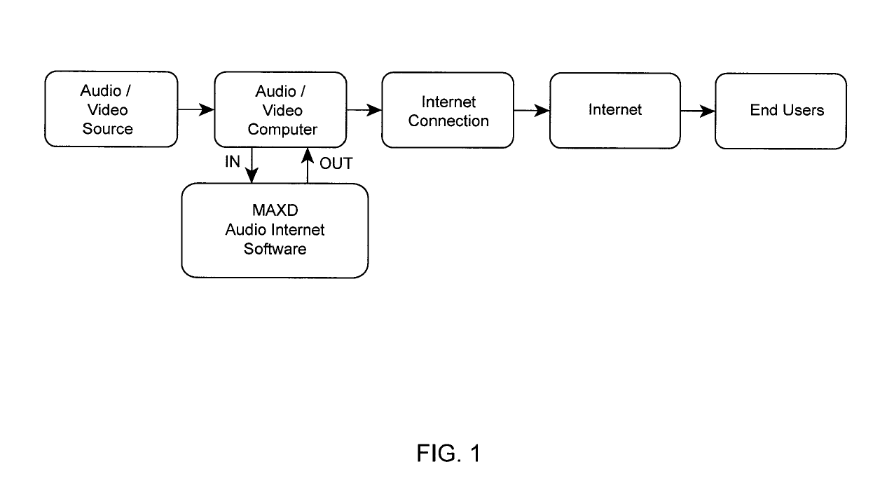

FIG. 2 is a block diagram showing the signal flow and the various processing blocks and steps according to an exemplary embodiment of the present invention.

FIG. 3 is a representation of how the levels of Stereo Bus A and Stereo Output change according to each other according to an exemplary embodiment of the present invention.

### DETAILED DESCRIPTION OF THE PREFERRED EMBODIMENT(S)

Details of the present invention will now be discussed by reference to the drawings.

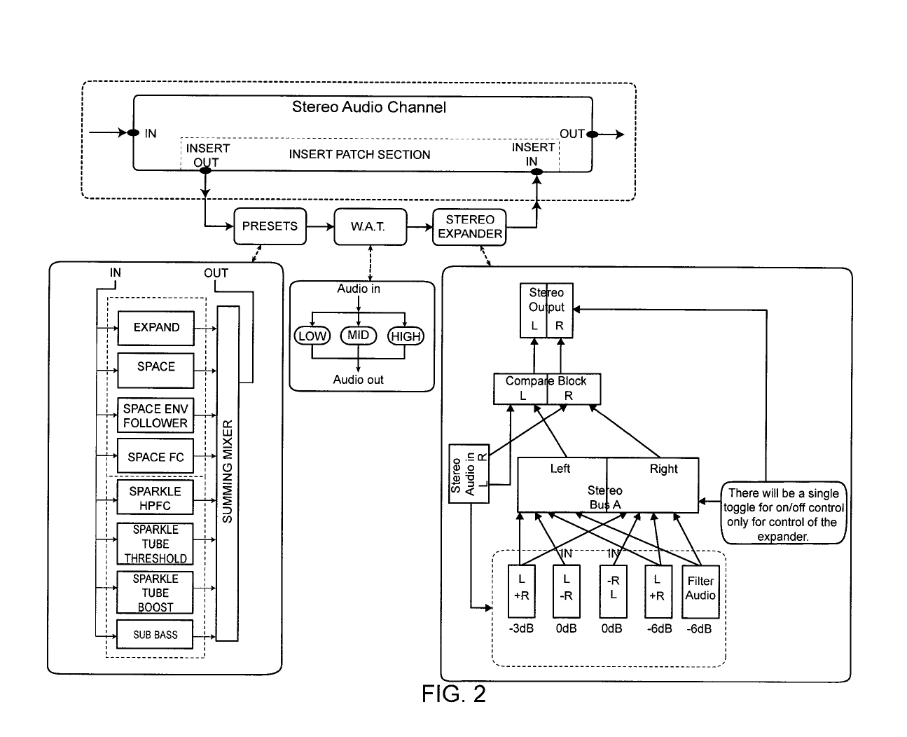

Referring to FIG. 2, in one exemplary embodiment, the initial audio signal is treated in four different ways in parallel and then combined with the original audio source in a mixer. The original audio signal is processed by EXPAND shown in FIG. 2. EXPAND is a low pass filter with dynamic offset. The frequency for the low pass filter can be about 40 k to 20 k hertz. In one embodiment, the frequency is about 2000 Hertz. Preferably, the range for EXPAND is 0-1, with intervals of 0.1. EXPAND can be preset in the program.

Referring to FIG. 2, the original audio signal is also processed by SPACE, which depicts three blocks for SPACE. The top block “SPACE” is the output level for this block. The next block is the envelope follower modulation amount, and the last block is the frequency range for SPACE block. The SPACE is an envelope controlled bandpass filter. The output amplitude for space can be set from about 0 to 3, such as about 1.8. The frequency range for SPACE is preferably about 1000 to about 8000 Hertz. The settings for SPACE can also be preset.

The original audio signal is also processed by SPARKLE. In one exemplary embodiment shown in FIG. 2 SPARKLE includes three blocks. The top block is the output level for this block, the SPARKLE HPFC set HP filter frequency, and SPARKLE TUBE BOOST sets amount of tube simulator sound. SPARKLE is a high pass filter. The frequency for the high pass filter is preferably about 4000 to about 10000 Hertz. The tube simulator is preferably set in single digits from 1-5. The threshold preferably ranges from 0-1 in 0.1 intervals. The settings for SPARKLE may be preset.

The original audio signal is also processed by SUB BASS, which adds an amount of dynamic synthesized sub bass to the audio. The frequency of the sub bass is preferably about 120 Hz or less.

The four treated audio signals (EXPAND, SPACE, SPARKLE, SUB BASS) are combined in a summing mixer to produce an audio signal with improved quality.

The individual modules referenced above will now be discussed in more detail.

EXPAND—is a 4 pole digital low pass filter with an envelope follower for dynamic offset (FIXED ENVELOPE FOLLOWER). This allows the output of the filter to be dynamically controlled so that the output level is equal to whatever the input is to this filter section. For example, if the level at the input is −6 dB, then the output will match that. Whenever there is a change at the input, the same change will occur at the output regardless of either positive or negative amounts. The frequency for this filter is 20 to 20 k hertz, in other words it is full range. The purpose of this filter is to “warm up” or provide a fuller sound as audio that passes through it. The original sound passes through, and is added to the effected sound for its output. As the input amount increases or decreases (varies), so does the phase of this section. Preferably, the filters are of the Butterworth type.

SPACE—There are several components to this module. They are: SPACE—this amount is after the envelope follower and sets the final level of this module. This is the effected signal only, without the original. SPACE ENV FOLLOWER—tracks the input amount and forces the output level of this section to match. SPACE FC—sets the center frequency of the 4 pole digital high pass filter used in this section. This filter also changes phase as does EXPAND.

SPARKLE—There are several components to this module. They are: SPARKLE HPFC—This is a 2 pole high pass filter with a preboost which sets the lower frequency limit of this filter. Anything above this setting passes through the filter while anything below is discarded or stopped from passing. SPARKLE TUBE THRESH—sets the lower level at which the tube simulator begins working. As the input increases, so does the amount of the tube sound. The tube sound is adding harmonics, compression and a slight bit of distortion to the input sound. This amount increases slightly as the input level increases. SPARKLE TUBE BOOST—sets the final level of the output of this module. This is the effected signal only, without the original.

SUB BASS—this module takes the input signal and uses a low pass filter to set the upper frequency limit to about 100 Hz. An octave divider occurs in the software that changes the input signal to lower by an octave (12 semi tones) and output to the only control in the interface, which is the level or the final amount. This is the effected signal only, without the original.

These modules are fed to a summing mixer which combines the audio. The levels going into the summing mixer are controlled by the various outputs of the modules listed above. As they all combine with the original signal, there is interaction in phase, time and frequencies that occur dynamically. These changes all combine to create a highly accurate sonic picture of a selected target area. This allows the operator to identify targets that would have been unseen without the aid of this process.

The Wave Adjustment Tool (WAT©) will now be discussed in detail with reference to an exemplary embodiment of the present invention. WAT© is a different approach in that it dynamically monitors the content and adjusts itself to compensate for these changes in both a positive and negative direction. The end result is very pleasing and a more natural sound of the content being played. WAT© is not limited only three bands. More dynamic bands may be added as desired by programming them into the process and assigning the frequency, band width, and amount of dynamic change to be allowed per band. Preferably, WAT is a digital process, but it may be hardware (analog) if desired in any output format (mono, stereo, 5.1, 7,1, etc.) In one embodiment, WAT© is a three section tone adjusting circuit with some dynamic control. The sections are LOW (bass), MID, and HIGH (treble). LOW—100 Hz @0.5 bandwidth. MID—2500 Hz @ adjustable bandwidth. The center frequency is dynamically moved in both positive and negative amounts according to the input level of this bandpass filter. The range is preferably from 1.7 kHz on the low end to 4.5 kHz on the upper end with 2.5 kHz as the center or nominal setting. As the input level goes positive or negative, so the bandwidth will change. For a negative change the bandwidth will increase to a 0.5, while a positive change will decrease to a 0.1. This gives you a larger frequency change for negative and a smaller, more precise change for positive level amounts in the filtered audio content. HIGH—10 kHz @ adjustable bandwidth. The center frequency is fixed at 10 kHz, but the bandwidth changes dynamically in positive amounts as the input level changes. For negative amounts the bandwidth stays at 0.5, when the level decreases the bandwidth goes only to a max bandwidth of 0.3.

STEREO EXPANDER: Modern music has little to no stereo field due to the amount of audio compression or even data compression into a lower format (Mp3, AAC, etc.). The purpose of this soundfield expander is to make a wider stereo image (a simulated distance increase between the left and right audio) for the listener to enjoy. This works particularly well with headphones. An end user will be able to control an amount of the effect on the soundfield to their liking with this process. The conventional way to create an expanded stereo field is by using some type of delay, like chorus effect, reverb, or a simple delay on one side of the stereo audio. This creates an unrealistic soundfield. Using these kinds of effects, either independently or combined, for the soundfield expansion creates very strong and very audible phase problems. Sometimes this type of effect can cause a ringing effect as a comb filter would. The Soundfield Expander doesn't exhibit these problems. The inventive Stereo Expander works in a dynamic fashion which almost entirely deletes these audible issues. The end result is a clear, highly defined soundfield expansion with a greater amount of intelligibility. In one embodiment, the “audio expander” is a stand alone software.

In one embodiment, the audio expander is designed and intended to be used in the smart phone App as an enhancement to the existing App. It is intended to expand the spatial properties of existing audio. This can be used for both digital and analog audio listening devices and playback units.

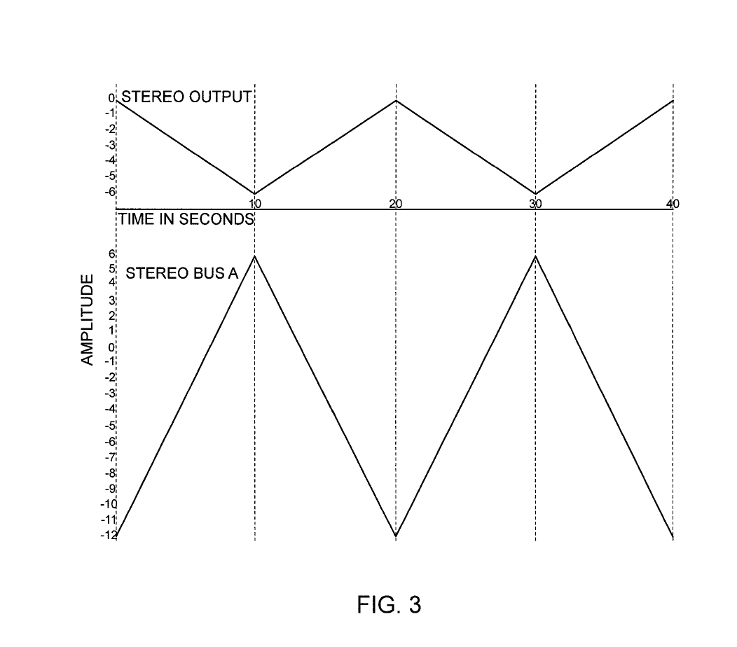

Referring to FIG. 2, the inventive process starts by taking the incoming audio and sending it into a block that splits, processes and combines the stereo stream into several different versions that are fed into the Stereo Bus A. Stereo Bus A is fed into a Compare Block that adjusts the amplitude of the original and processed audio by averaging. In one embodiment, there is a fixed ratio of 2.75 (Stereo Bus A) to 1 (Original Stereo Source) that operates in both positive and negative directions. The end result is an expanded stereo field that both expands and contracts as real audio does. There will be a single “slider” or Stereo Amount that will adjust the mix of the audio from a zero to maximum amount with only a slight gain change in the overall amplitude. In addition, the amount could be driven by an envelope follower to create a dynamic soundfield that changes according to the setting of the envelope follower. The STEREO SOURCE is mixed with the STEREO BUS A. Next it goes into the Compare Block where the output signal stays very close to a constant amount. There are two separate tables for accomplishing this and are shown in FIG. 3. As the Stereo Amount slider moves up and down, it moves the values in FIG. 3 a corresponding amount to keep the level close to the same. In one embodiment, it follows the dB amounts shown in FIG. 3. As the control slider (Stereo Amount) moves up and down, it changes the values in a corresponding amount to keep the level close to the same.

Referring to FIG. 2, various blocks are now explained in more detail according to an exemplary embodiment. Blocks are: 1. L+R—the original left and right summed together and the output panned to center. 2. L−R—the original left and right with the right inverted and summed together. The output is panned to the left. 3. −R L—the original left and right with the left inverted and summed together. The output is panned to the right. 4. L+R—the original left and right summed together and panned to the center. This level is 6 dB lower than the original. 5. Filler Audio—the original left and right summed together and the output panned to center. There is a bandpass filter set for 55 Hz to 8.5 kHz. A delay is set for 30 ms for the left side only. The above blocks feed into Stereo Bus A. Their levels are shown in FIG. 2.

Compare Block—Referring to FIG. 2 and above explanation, both the Stereo Bus A and Stereo Output levels are controlled by a single control fader in the GUI. Their levels are shown in FIGS. 2 (−12 to +6 dB).

FIG. 3 is a representation of how the levels of Stereo Bus A and Stereo Output change in relation to each other. Even though there are two complete cycles show, there is no modulation source; this is only to show an example of turning the control fader fully up and down twice. This will ensure that the output doesn't have a great increase as the Stereo Bus A level is increased.

What is claimed is:

1. An audio enhancement technique comprising:
an audio source;
Setting presets for the input audio sound to create a presetted audio sound;
Tone adjusting the presetted audio sound to create a tone adjusted presetted audio;
Expanding the tone adjusted presetted audio to create an expanded audio;
Outputting the expanded audio.

2. The process of claim 1, wherein the presetted audio is subjected to a treatment by one or more modules to improve sound quality.

3. The process of claim 1, wherein the treatment comprises processing the audio source by the following modules:
a low pass filter with dynamic offset;
an envelope controlled bandpass filter;
a high pass filter; and
adding an amount of dynamic synthesized sub bass to the audio;
combining the processed audio signals in a summing mixer with the audio source to create an audio out signal.

4. The process of claim 1, wherein the expanding comprises sending audio out to a block that splits, processes and combines the stereo stream into several different versions that are fed into the Stereo Bus A;
Feeding Stereo Bus A output to a Compare Block that adjusts the amplitude of the original and processed audio by averaging;
Feeding the output from the compare block as an stereo output.

5. The process of claim 1, wherein the presetting comprises ten or more presets corresponding to genres of music.

6. The process of claim 1, wherein the presetting comprises an auto present that is selected by genre in metadata of playback material.

7. The process of claim 1, wherein the presetting comprises a single generic preset that covers all types of music.

8. The process of claim 1, wherein the tone adjustment comprises;
A first section for adjusting a low frequency tone;
A second section for adjusting a mid frequency tone;
A third section for adjusting a high frequency tone; and
Mixing the audio outputs processed by the first, second and third sections to produce an output audio sound.

9. The process of claim 8, wherein the low frequency tone has a frequency of 100 Hz and a bandwidth of 0.5.

10. The process of claim 8, wherein the mid frequency tone has a frequency of 2500 Hz and an adjustable bandwidth.

11. The process of claim 8, wherein the high frequency tone has a frequency of 10 KHz and an adjustable bandwidth.
